(19) United States
(12) Patent Application Publication
(10) Pub. No.: US 2015/0331019 A1
(43) Pub. Date: Nov. 19, 2015

(54) CURRENT MEASUREMENT DEVICE

(71) Applicant: FUJI ELECTRIC CO., LTD., Kanagawa (JP)

(72) Inventor: Seini Yamamura, Kanagawa (JP)

(21) Appl. No.: 14/765,220

(22) PCT Filed: Jul. 22, 2014
(86) PCT No.: PCT/JP2014/003853

§ 371 Date: Jul. 31, 2015

(30) Foreign Application Priority Data
Jul. 23, 2013 (JP) 2013-152594

(51) Int. Cl. G01R 19/165

(52) U.S. Cl. CPC G01R 19/16566

(57) ABSTRACT

A current measurement device includes: an integration circuit which integrates the current to be measured, and outputs an integral signal; a low range current measurement unit which receives the integral signal output from the integration circuit and calculates a low range current measurement value that is proportional to the rate of change of the integral signal; a high range current measurement unit which calculates a high range current measurement value based on a pulse signal corresponding to the cycle of the integral signal; a pumping circuit which, using the pulse signal, discharges a charge stored in the integration circuit; and a measurement value determination unit which determines a measurement value of the current to be measured based on the low range current measurement value calculated by the low range current measurement unit, and the high range current measurement value calculated by the high range current measurement unit.

### TECHNICAL FIELD

The present disclosure relates to a current measurement device which is capable of measuring a minute current over a wide range of current values, in a short period of time, and accurately.

### BACKGROUND

As a current measurement device that measures an output current of an ionization chamber radiation detector, a current/frequency conversion device disclosed in, for example, Japanese Patent No. 4479430 has been proposed. The current/frequency conversion device includes an integration amplification circuit that stores an input current as charge and outputs a voltage that is proportional to the stored charge, a frequency conversion circuit that outputs a pulse signal that has a frequency proportional to the voltage output from the integration amplification circuit and a duty ratio of 50%, and a pumping circuit that discharges the charge stored in the integration circuit when the pulse signal is supplied.

### SUMMARY OF THE DISCLOSURE

To cover a wide range of measured current from 10⁻¹⁵ A to 10⁻⁶ A (up to 9 digits) as the output current from the ionization chamber radiation detector, the current/frequency conversion device disclosed in Japanese Patent No. 4479430 outputs a signal with a frequency of approximately 0.001 Hz for a minimum current, causing a response time to obtain a measurement result to become 1000 seconds. To achieve a response time of, for example, 1 second, it is required to set the frequency of an output signal for a minimum current at 1 Hz or higher, causing the minimum current of a range of measured current to increase by 3 digits and, thus, the range of measured current to decrease accordingly.

Therefore, to secure a response time of, for example, 1 second and widen a range of measured current, a method is used in which a plurality of circuit constants with different ranges of measurable current are implemented in advance and the circuit constants are switched in accordance with a current to be measured.

However, there is an unresolved problem in that, because a time to switch current ranges is required in switching the current ranges, the response is delayed by a time equivalent to the switching time.

Accordingly, the present disclosure is made in consideration of the above-described unresolved problem, and has an object to provide a current measurement device by which it is possible to measure a wide range of a minute current accurately in a short period of time.

To achieve the above-described object, according to an aspect of the present disclosure, there is provided a current measurement device, a current measurement range of a current to be measured by the current measurement device being divided into at least a low range and a high range, the current measurement device carrying out current measurement in each of the low range and the high range. The current measurement device includes an integration circuit configured to integrate the current to be measured and output an integral signal, a low range current measurement unit configured to receive the integral signal output from the integration circuit and calculate a low range current measurement value that is proportional to a rate of change of the integral signal, a high range current measurement unit configured to calculate a high range current measurement value based on a pulse signal corresponding to a cycle of the integral signal output from the integration circuit, a pumping circuit configured to discharge charge stored in the integration circuit based on the pulse signal, and a measurement value determination unit configured to determine a measurement value of the current to be measured based on the low range current measurement value calculated by the low range current measurement unit and the high range current measurement value calculated by the high range current measurement unit.

According to an aspect of the present disclosure, an integral signal of a current to be measured is supplied to both a low range current measurement unit and a high range current measurement unit, the low range current measurement unit calculates a current measurement value that is proportional to the rate of change of the integral signal, and the high range current measurement unit calculates a current measurement value based on a pulse signal corresponding to the frequency of the integral signal. Therefore, by using a current measurement value calculated by the low range current measurement unit when the current to be measured has a low range value and using a current measurement value calculated by the high range current measurement unit when the current to be measured has a high range value, it is possible to measure the current over a wide range of current values, in a short period of time, and accurately.

### BRIEF DESCRIPTION OF DRAWINGS

FIG. 1 is a block diagram illustrating a schematic configuration of a first embodiment as an aspect of a current measurement device according to the present disclosure;

FIG. 2 is a block diagram illustrating a specific configuration of the current measurement device in FIG. 1;

FIG. 3 is a flowchart illustrating an example of a low range current measurement processing carried out by an arithmetic processing circuit;

FIG. 4 is a flowchart illustrating an example of a high range current measurement processing carried out by the arithmetic processing circuit;

FIG. 5 is a flowchart illustrating an example of a high range current measurement value storage area invalidation processing carried out by the arithmetic processing circuit;

FIG. 6 is a flowchart illustrating an example of a measurement value determination processing carried out by the arithmetic processing circuit;

FIGS. 7A to 7E are timing diagrams for a description of operations of the first embodiment;

FIGS. 8A and 8B are explanatory diagrams illustrating a relationship between values of a current to be measured and the rate of change of an integrated voltage signal in a low range current measurement unit and a relationship between values of the current to be measured and the frequency of the integrated voltage signal in a high range current measurement unit;

FIG. 9 is a block diagram illustrating a second embodiment as another aspect of the present disclosure;

FIGS. 10A to 10G are timing diagrams for a description of operations of the second embodiment; and

FIGS. 11A to 11E are timing diagrams for a description of operations for a case in which an initialization circuit is not disposed.

### DETAILED DESCRIPTION

Embodiments of the present disclosure will be described below with reference to the drawings.

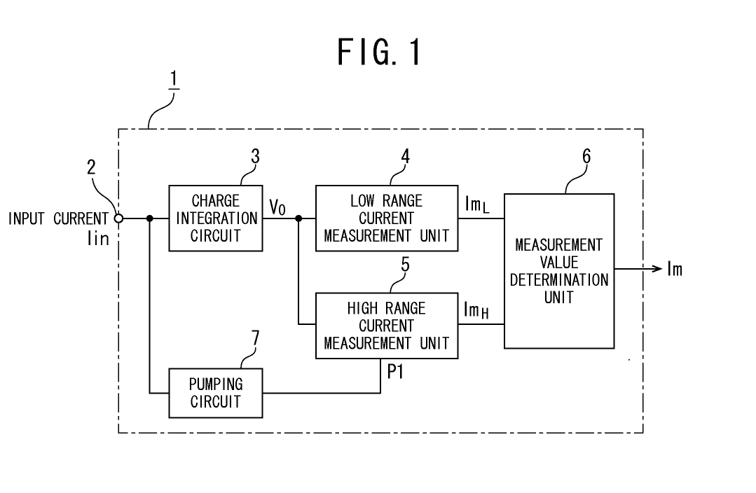

FIG. 1 is a block diagram illustrating a schematic configuration of a first embodiment as an aspect of the present disclosure.

A current measurement device 1 according to the present disclosure includes, as illustrated in FIG. 1, a current input terminal 2 to which a current to be measured Iin is input and a charge integration circuit 3 as an integration circuit, which is connected to the current input terminal 2. The current measurement device 1 also includes a low range current measurement unit 4 and a high range current measurement unit 5 into which an integrated voltage signal as an integral signal, which is output from the charge integration circuit 3, is input and includes a measurement value determination unit 6 configured to determine a measurement value based on measurement values calculated by the low range current measurement unit 4 and the high range current measurement unit 5. Further, the current measurement device 1 includes a pumping circuit 7 configured to discharge a certain amount of charge stored by the charge integration circuit 3.

The current to be measured Iin is a negative minute current with a wide measured current range of from 10⁻¹⁵ A (1 fA) to 10⁻⁶ A (1 μA) (up to 9 digits) as, for example, an output current from an ionization chamber radiation detector.

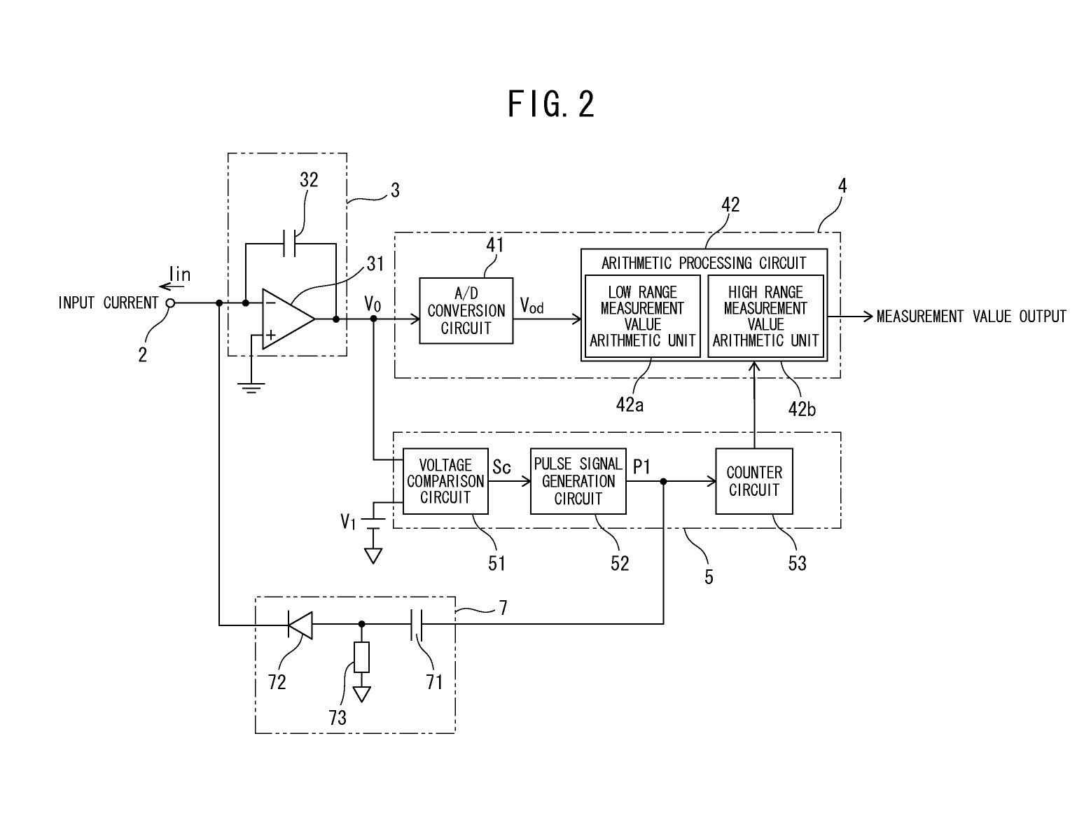

A specific configuration of the charge integration circuit 3, as illustrated in FIG. 2, includes an operational amplifier 31 having an inverting input terminal to which the current to be measured Iin is supplied and a non-inverting input terminal that is grounded, and an integrating capacitor 32 which is connected between the output terminal and the inverting input terminal of the operational amplifier 31. Thus, in the charge integration circuit 3, if it is assumed that the capacitance of the integrating capacitor 32 is denoted by C, when a negative current to be measured Iin is input, a positive integrated voltage signal Vo, which is an integral of the input current to be measured and expressed by the following formula (1), is output.

$$Vo = - \frac{1}{C} {\int }_{T = 0}^{T} Iin d t = - \frac{1}{C} Iin \cdot T$$

As it is obvious from formula (1), the integrated voltage signal Vo from the operational amplifier 31 rises in proportion to elapsed time T. At this time, charge Q (=C×Vo) of an amount equivalent to a product of the output integrated voltage signal Vo multiplied by the capacitance C of the capacitor is stored in the integrating capacitor 32.

A specific configuration of the low range current measurement unit 4, as illustrated in FIG. 2, includes an analog to digital (A/D) conversion circuit 41 configured to read the integrated voltage signal Vo output from the charge integration circuit 3 with a predetermined sampling period (for example, approximately 1 s) and convert the integrated voltage signal Vo to a digital signal and an arithmetic processing circuit 42 as a low range measurement value arithmetic unit, to which the digital signal output from the A/D conversion circuit 41 is input and which is configured with, for example, a microcomputer.

The arithmetic processing circuit 42 includes a low range measurement value arithmetic unit 42a configured to carry out low range current measurement processing based on at least a digital signal Vod output from the A/D conversion circuit 41 and a high range measurement value arithmetic unit 42b configured to carry out high range current measurement processing as timer interrupt processing for every predetermined period (for example, 125 ms).

The arithmetic processing circuit 42 makes the low range measurement value arithmetic unit 42a carry out the low range current measurement processing based on the digital signal Vod output from the A/D conversion circuit 41 to calculate a rate of change Rc per unit time of the integrated voltage signal Vo, and calculate, by multiplying the calculated rate of change Rc by a conversion factor Kc (for example, “1”), a low range current measurement value Im_{L} (=Rc×Kc).

The low range current measurement processing is, for example, carried out as timer interrupt processing for every predetermined period (for example, 1 second), which is set to the same as the sampling period of the A/D conversion circuit 41.

When a pulse signal P1 output from a pulse signal generation circuit 52 as described later causes sampling to be carried out while charge stored in the integrating capacitor 32 of the charge integration circuit 3 is being pumped, digital signals Vod(n) from the A/D conversion circuit 41 are discarded because the integrated voltage signal Vo from the operational amplifier 31 of the charge integration circuit 3 has changed so steeply that the proportionality between the rate of change Rc per unit time of the integrated voltage signal Vo and the current to be measured Iin has been lost. Thus, the digital signals Vod(n) are not usable for calculation of the current to be measured Iin.

The number of digital signals Vod(n) to be discarded may be at most one because the digital signals Vod(n) to be discarded are signals sampled while charge is pumped and, in the embodiment, when sampling is carried out while charge is pumped, the next timing of sampling is configured to always come after the charge has been pumped. When a plurality of times of sampling are carried out while charge is pumped, a number of digital signals Vod(n) that is equal to the number of times of sampling may be discarded.

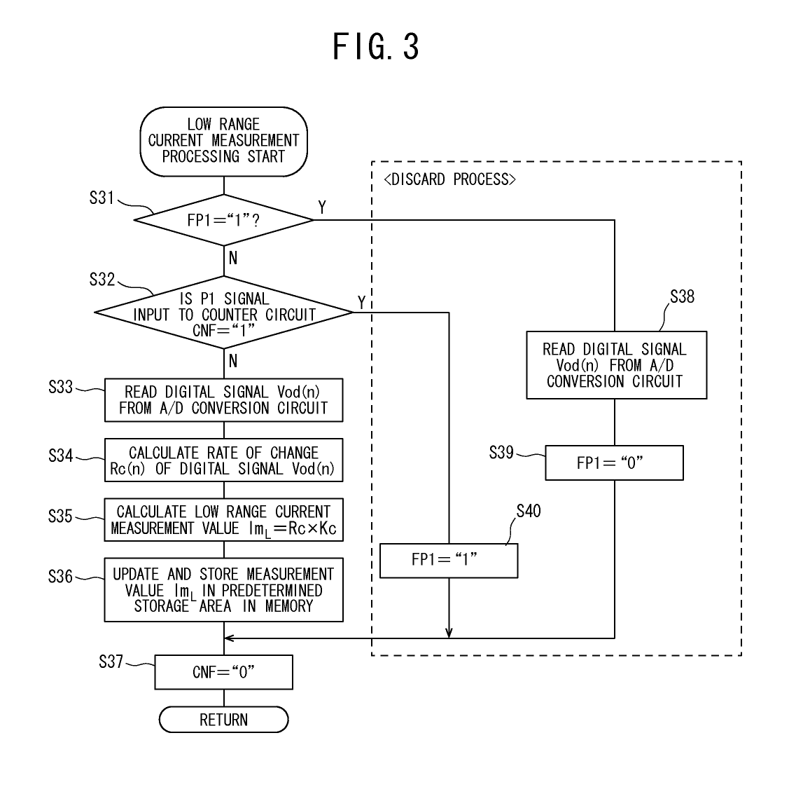

To cause such processing to be carried out, as illustrated in FIG. 3, the low range current measurement processing first carries out decision, in step S31, with reference to a flag FP1 which indicates whether or not the next processing is discard processing of the digital signal(s) Vod(n). When FP1 is equal to “0”, the process proceeds to step S32.

In step S32, in the processing different than discard processing of the digital signal(s) Vod(n) from the A/D conversion circuit 41, it is determined whether or not a signal P1 has been input to a counter circuit 53 from a pulse signal generation circuit 52 after the last sampling referring to a flag CNF. When there has been no input of the signal P1 (CNF=“0”), the process proceeds to step S33. In contrast, when there has been an input of the signal P1 (CNF=“1”), the process proceeds to step S40 in the discard processing.

In step S34, a rate of change per unit time Rc is calculated (differentiation processing) as a difference (Vod(n)−Vod(n−1)) between the digital signal Vod(n), which is read in step S33, and the digital signal Vod(n−1), which has been read the last time, divided by a timer interrupt period Tt. Then, the process proceeds to step S35. The digital signal Vod(n−1), which has been read the last time, includes a digital signal Vod which has been read in step S38 just before the end of the discard processing described later.

In this step S35, by multiplying the rate of change Rc, which is calculated in step S34, by the conversion factor Kc (for example, “1”), the low range current measurement value Im_{L} (=Rc×Kc) is calculated. Next, the process proceeds to step S36, the low range current measurement value Im_{L} calculated in step S35 is updated and stored in a low range current measurement value storage area, which is arranged in a memory included in the arithmetic processing circuit 42, and the process proceeds to step S37.

Discard Processing

Discard processing of a digital signal Vod, which is output from the A/D conversion circuit 41, when the digital signal Vod is sampled while charge stored in the integrating capacitor 32 of the charge integration circuit 3 is pumped is carried out with a procedure described below.

It is determined in step S32 whether or not the process proceeds to the discard processing. In step S32, when the signal P1 is input to the counter circuit 53 from the pulse signal generation circuit 52 (CNF=“1”), the process proceeds to step S40 in the discard processing. In the discard processing, a digital signal Vod(n) from the A/D conversion circuit 41, which has lost proportionality to the input current, is discarded without being read. Then, the process proceeds to step S40, where the flag FP1, which indicates that process should proceed to the discard processing, is set at “1”, and the process proceeds to step S37. After processing in step S37 described later is carried out, the timer interrupt processing is ended, and the process returns to a predetermined main program.

In step S31 in the next round of the low range current measurement processing, when the flag FP1=“1” (in the discard processing), the process proceeds to step S38. The digital signal Vod(n) is read and held in step S38, so that a rate of change is calculated in step S34 in the next round of the low range current measurement processing, the flag FP1 is set at “0” in step S39, and the process proceeds to step S37.

In step S37, the flag CNF, which indicates there has been an input of the pulse signal P1 in the counter circuit, is set at “0” so that it is possible to detect an input of the pulse signal P1 to the counter circuit 53 after the current round of the low range current measurement processing, the timer interrupt processing is then ended, and the process returns to the predetermined main program.

The high range current measurement unit 5, as illustrated in FIG. 2, includes a voltage comparison circuit 51, the pulse signal generation circuit 52, and the counter circuit 53.

When the integrated voltage signal Vo output from the afore-described charge integration circuit 3 is less than a reference voltage V1, the voltage comparison circuit 51 outputs, for example, a low-level comparison signal Sc. When the integrated voltage signal Vo reaches the reference voltage V1, the voltage comparison circuit 51 outputs a high-level comparison signal Sc.

The pulse signal generation circuit 52 is configured with, for example, a monostable multivibrator, which outputs a pulse signal P1 with a predetermined pulse width and a predetermined pulse wave height when the comparison signal Sc reverses from the low-level to the high-level.

The counter circuit 53 counts clock pulses for a duration from the time at which a pulse signal P1(n) output from the pulse signal generation circuit 52 is input until the next pulse signal P1(n+1) is input and calculates a cycle T of the pulse signal P1. The cycle T, which is a count value of the counter circuit 53, is input to the afore-described arithmetic processing circuit 42.

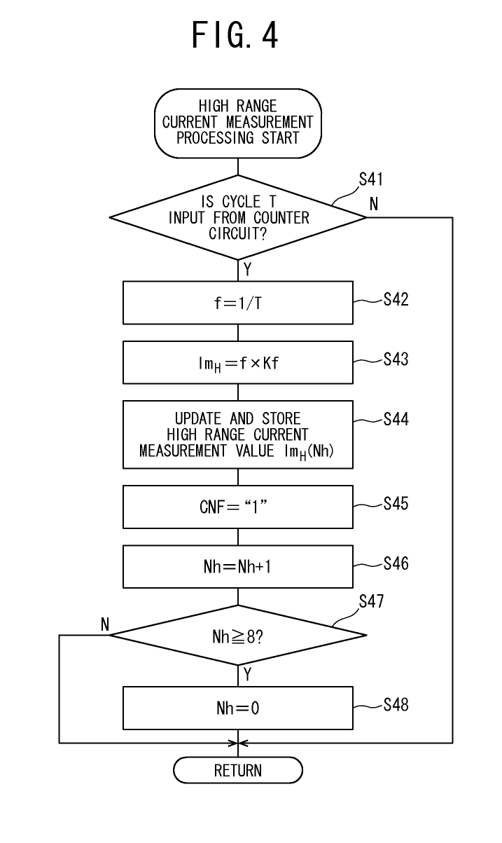

The arithmetic processing circuit 42 makes the high range measurement value arithmetic unit 42b carry out high range current measurement processing illustrated in FIG. 4. The high range current measurement processing is carried out as timer interrupt processing for every predetermined period (for example, 125 ms), holds high range current measurement values calculated by the high range current measurement processing from the latest value back to the past values for a predetermined period (for example, 8 values for 1 second), and updates the high range current measurement values successively with the following procedure.

First, in step S41, it is determined whether or not the cycle T, which is a count value, of the integrated voltage signal Vo is input from the counter circuit 53. When the cycle T has not been input from the counter circuit 53, the timer interrupt processing is ended without any processing and the process returns to the predetermined main program. When the cycle T has been input from the counter circuit 53, the process proceeds to step S42.

In this step S42, a frequency f is calculated by carrying out a calculation expressed by the following Formula (2) based on the cycle T.

f=1/T

Then, the process proceeds to step S43, where a high range current measurement value ImH is calculated by multiplying the calculated frequency f by a conversion factor Kf (for example, “1”), and, then, the process proceeds to step S44. At step S44, the calculated high range current measurement value Im_{H} is updated and stored in a high range current measurement value storage area Im_{H}(Nh) in the memory. Nh is a numerical value to distinguish storage areas for high range current measurement values for a past predetermined period in the high range current measurement value storage area, and, in the embodiment, Nh takes values of 0 to 7 because 8 storage areas for 1 second are distinguished.

The process next proceeds to step S45, the flag CNF, which indicates whether or not the pulse signal P1 has been input, is set at “1” in the counter circuit, and, then, the process proceeds to step S46.

Steps S46 to S48 are processing to update the value (Nh of Im_{H}(Nh)) to distinguish storage areas for high range current measurement values in the next round of the high range current measurement processing or a high range current measurement value area invalidation processing. Namely, in step S46, Nh is increased by 1. Then, in step S47, it is determined whether or not a condition “Nh≧8” is satisfied. When the condition is satisfied, Nh is set at 0 in step S48; the timer interrupt processing is ended; and the process returns to the predetermined main program.

On the other hand, when, in step S47, the condition is not satisfied, that is, Nh<8, the timer interrupt processing is ended without any processing and the process returns to the predetermined main program.

When the high range current measurement value storage areas Im_{H}(0) to Im_{H}(7) are not updated even if a predetermined period (for example, 2 seconds) has passed, “0” is written into a high range current measurement value storage area Im_{H}(Nh) which is to be updated next time to make data in the high range current measurement value storage area Im_{H}(Nh) invalid.

Thereafter, it is determined once every second whether or not the high range current measurement value storage areas Im_{H}(0) to Im_{H}(7) is updated, and, when the high range current measurement value storage areas Im_{H}(0) to Im_{H}(7) are not updated, “0” is written into a high range current measurement value storage area Im_{H}(Nh) successively to make data in the high range current measurement value storage area Im_{H}(Nh) invalid.

This processing, when an input current takes a value on the boundary between the low range current region and the high range current region (in the embodiment, the cycle T from the counter circuit 53 takes a value of 2 to 8 seconds), calculates a measurement value of the input current by using both a low range current measurement value Im_{L} and high range current measurement values Im_{H}. This processing, in the calculation, reduces discontinuity in the measurement values due to a difference between the sensitivity of the low range current measurement value Im_{L} and the sensitivity of the high range current measurement values Im_{H} by increasing the number of pieces of invalid data in the high range current measurement value storage areas Im_{H}(Nh) to lessen weight of the high range current measurement values Im_{H} as the current decreases.

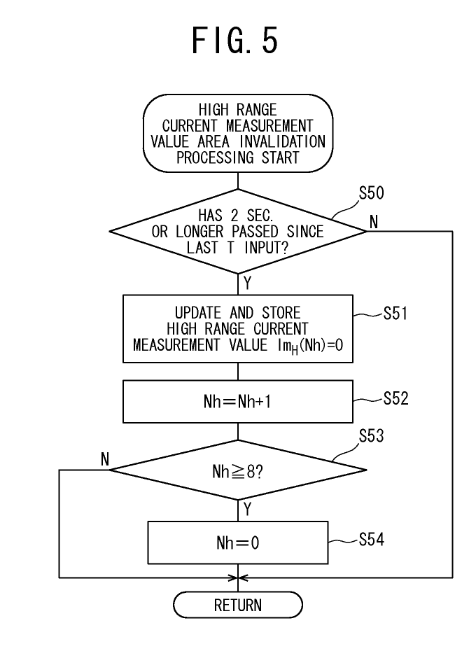

A specific procedure of the processing will be described with reference to FIG. 5.

The arithmetic processing circuit 42 carries out high range current measurement value storage area Im_{H}(Nh) invalidation processing illustrated in FIG. 5. This processing is carried out as timer interrupt processing for every predetermined period (for example, 1 second).

First, in step S50, a count value of the clock counted by the counter circuit 53 is read, and, based on the count value, it is determined whether or not 2 seconds or longer has passed since the cycle T was input the last time. When less than 2 seconds has passed since the last input of the cycle T, the timer interrupt processing is ended without any processing and the process returns to the predetermined main program. In contrast, when 2 seconds or longer has passed since the last input of the cycle T, the process proceeds to step S51.

In step S51, “0” is written into a high range current measurement value storage area Im_{H}(Nh) which is to be updated next time to make data in the high range current measurement value storage area Im_{H}(Nh) invalid, and the process proceeds to step S52.

Steps S52 to S54 are processing to update a value (Nh in Im_{H}(Nh)) that distinguishes storage areas for 8 high range current measurement values in the next round of the high range current measurement value area invalidation processing or the high range current measurement processing. Namely in step S52, Nh is increased by 1. Then, in step S53, it is determined whether or not a condition “Nh≧8” is satisfied. When the condition is satisfied, Nh is set at 0 in step S54, the timer interrupt processing is ended, and the process returns to the predetermined main program.

On the other hand, when the condition is not satisfied, that is, Nh<8 in step S53, the timer interrupt processing is ended without any processing and the process returns to the predetermined main program.

Because a series of processing illustrated in FIG. 5 is carried out in interrupt processing with a period of 1 second, when the pulse signal P1 from the pulse signal generation circuit 52 keeps ceasing to be output for 2 seconds or longer and this state lasts 8 seconds, all values in the high range current measurement value storage areas (Im_{H}(Nh)), which store eight high range current measurement values, become invalid, that is, “0”.

On the other hand, when the pulse signal P1 is input to the counter circuit 53, a high range current measurement value storage area (Im_{H}(Nh)) specified by a value of Nh when the pulse signal P1 is input is updated with a high range current measurement value ImH in the afore-described high range current measurement processing.

Furthermore, the pumping circuit 7 includes a series circuit including a pumping capacitor 71 to which the pulse signal P1, which is output from the pulse signal generation circuit 52 of the high range current measurement unit 5, is input, and a pumping diode 72 the cathode of which is connected between the current input terminal 2 and the inverting input terminal of the operational amplifier 31 composing the charge integration circuit 3, and a resistor 73 which is interposed between the connection point of the pumping capacitor 71 and the pumping diode 72 and the ground.

In the pumping circuit 7, when the pulse signal P1 output from the pulse signal generation circuit 52 is at the low-level, charge stored in the pumping capacitor 71 is discharged via the resistor 73. The pumping diode 72 is thus in the off-state, causing the integrating capacitor 32 of the charge integration circuit 3 to maintain a charge stored state.

When the pulse signal P1 output from the pulse signal generation circuit 52 rises to the high-level from the above-described state, charge being charged in the pumping capacitor 71 flows to the ground via the resistor 73 during the rise, and a positive voltage is generated at the connection point of the pumping capacitor 71 and the resistor 73. Because the voltage is applied to the pumping diode 72 as a forward voltage, the pumping diode 72 conducts to make a current flow therethrough, causing charge stored in the integrating capacitor 32 of the charge integration circuit 3 to be pumped.

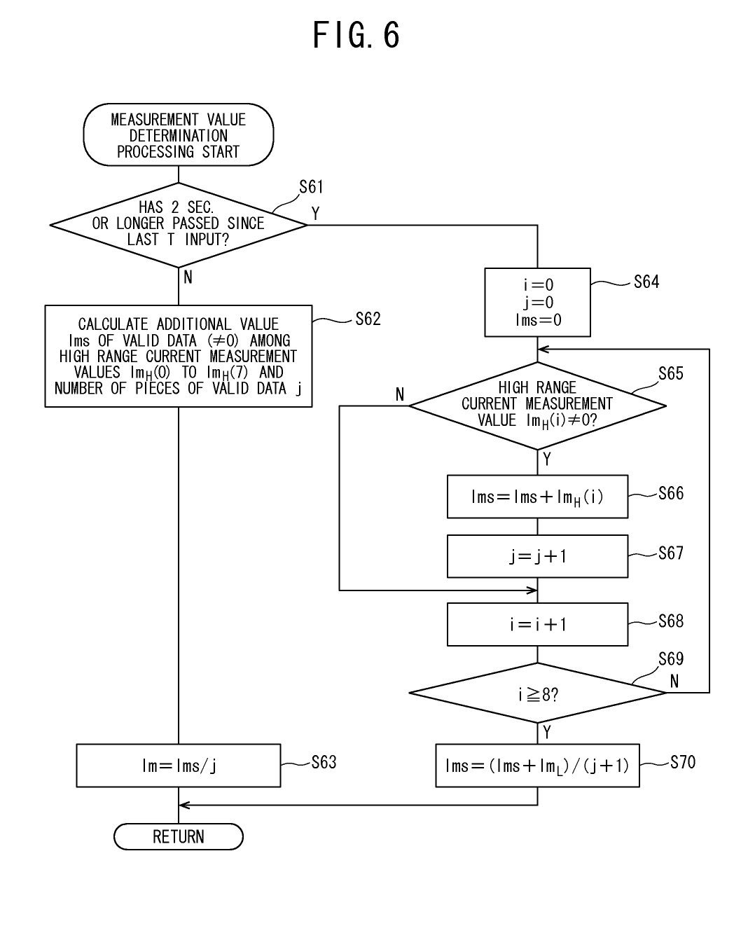

On the other hand, the arithmetic processing circuit 42 carries out measurement value determination processing illustrated in FIG. 6. The measurement value determination processing is carried out as timer interrupt processing which is carried out for every predetermined period (for example, 1 second).

First, in step S61, it is determined that whether or not 2 seconds or longer has passed since the cycle T was input from the counter circuit 53 the last time as described earlier.

When the result of the decision in step S61 shows that 2 seconds or longer has passed since the cycle T was input the last time, the process proceeds to step S64.

A series of processing starting from step S64 is processing to weight the high range current measurement values Im_{H} in accordance with the frequency of the pulse signal P1, and calculate an average value of the high range current measurement values Im_{H} and the low range current measurement value Im_{L} as a measurement value of the current to be measured Iin. In step S64, an initial value of i, which is a pointer to specify the location of a high range current measurement value storage area (Im_{H}(i)), is set at 0, an initial value of j, which is a register to count the number of pieces of valid data in the high range current measurement value storage areas (Im_{H}(i)), is set at 0, an initial value of Ims, which is a register to store a current measurement value in the process of being calculated, is set at 0, and the process proceeds to step S65.

In step S65, it is determined whether or not a value in the high range current measurement value storage area (Im_{H}(i)) specified by i is valid (Im_{H}(i)≠0), and, when the value is valid, the process proceeds to step S66. At step S66, the valid high range current measurement value Im_{H}(i) is added to Ims. The process then proceeds to step S67, where 1 is added to the number of pieces of valid data, and, then, the process proceeds to step S68. On the other hand, when it is determined in step S65 that a value in the high range current measurement value storage area (Im_{H}(i)) specified by i is invalid (Im_{H}(i)=0), the process proceeds to step S68 without any processing.

In step S68, 1 is added to the pointer i, which specifies the location of the high range current measurement value storage area (Im_{H}(i)), and the process returns to step S65 repeatedly until the pointer becomes 8 (the upper bound of the number of high range current measurement value storage areas) or greater in step S69. At step S69, the number of pieces of valid data j and the sum Ims of valid high range current measurement values are calculated, and, then, the process proceeds to step S70.

In step S70, by dividing a value obtained by adding the low range current measurement value Im_{L} to the sum Ims of valid high range current measurement values, which has been calculated previously, by a value obtained by adding 1 to the number of pieces of valid data j, an average value of these measurement values is calculated. The current measurement value Im is updated with the calculated average value, the timer interrupt processing is ended, and the process returns to the predetermined main program.

On the other hand, when it is determined in step S61 that 2 seconds or longer has not passed since the cycle T was input the last time, the process proceeds to step S62.

In step S62, the same processing as steps S64 to S69 is carried out, an additional value Ims of valid data (≠0) among the high range current measurement values Im_{H}(0) to Im_{H}(7) and the number of pieces of valid data j are calculated, and the process proceeds to step S63.

In step S63, an average value of the measurement values is calculated by dividing the sum Ims of valid high range current measurement values, which has been calculated previously, by the number of pieces of valid data j, the current measurement value Im is updated with the calculated average value, the timer interrupt processing is ended, and the process returns to the predetermined main program.

The A/D conversion circuit 41 and the low range current measurement value calculation processing carried out by the arithmetic processing circuit 42 correspond to the low range current measurement unit 4. The voltage comparison circuit 51, the pulse signal generation circuit 52, the counter circuit 53, and the high range current measurement value calculation processing and the high range current measurement value storage area invalidation processing carried out by the arithmetic processing circuit 42 correspond to the high range current measurement unit 5. Further, the measurement value determination processing carried out by the arithmetic processing circuit 42 corresponds to the measurement value determination unit 6.

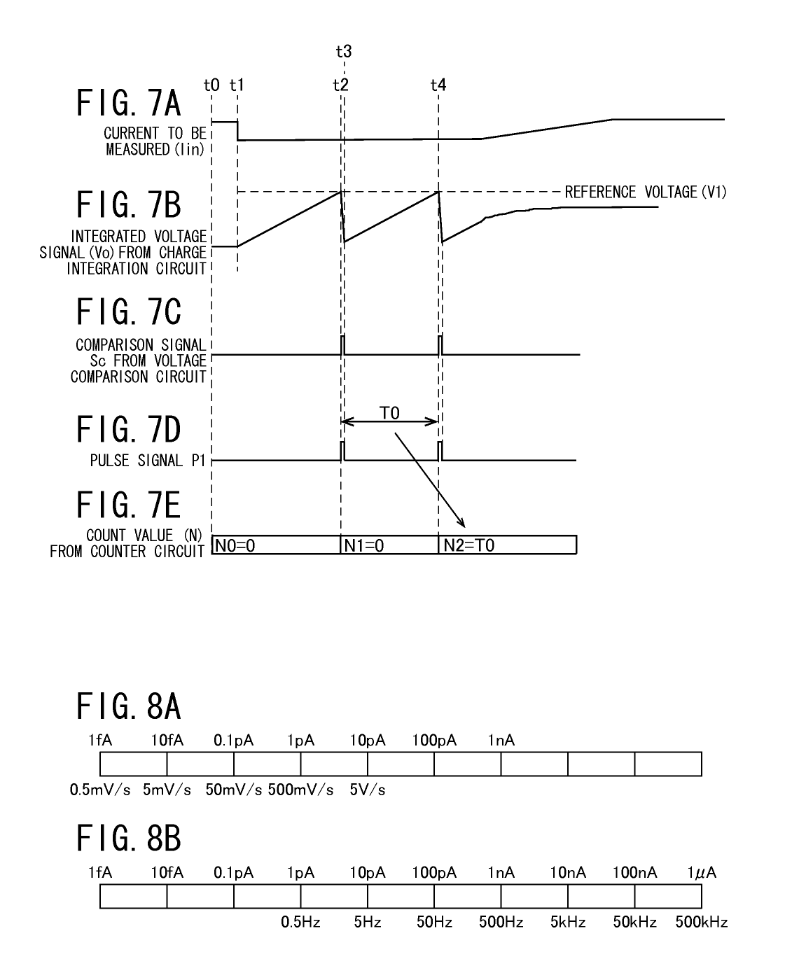

Next, operations of the above-described first embodiment will be described with reference to timing diagrams illustrated in FIGS. 7A to 7E.

It is assumed that the current to be measured Iin, which is to be input to the current input terminal 2, has not been input at a point of time t0 as illustrated in FIG. 7A, the integrated voltage signal Vo, which is output when the integrating capacitor 32 of the charge integration circuit 3 is discharged, is “0”, and the count value N of the counter circuit 53 of the high range current measurement unit 5 is cleared to “0”.

When the circuit is in this state and the current to be measured Iin with a negative fixed value of, for example, −10⁻¹² A or higher, is input at a point of time t1, the current to be measured Iin flows and is stored into the integrating capacitor 32 of the charge integration circuit 3. Thus, the integrated voltage signal Vo output from the charge integration circuit 3, as expressed by the afore-described formula (1), takes a value calculated as an integrated value of the current to be measured Iin divided by the capacitance C of the integrating capacitor 32. Therefore, when the current to be measured Iin takes a constant value, the integrated voltage signal Vo increases in proportion to elapsed time T as illustrated in FIG. 7B. At this time, charge Q of an amount equivalent to a product of the integrated voltage signal Vo of the operational amplifier 31 multiplied by the capacitance C of the integrating capacitor 32 (Q=C×Vo) has been stored in the integrating capacitor 32. Because, in this initial state, the integrated voltage signal Vo takes a value lower than the reference voltage V1, a comparison signal Sc output from the voltage comparison circuit 51 is maintained at the low-level as illustrated in FIG. 7C.

Because, subsequently, the current to be measured Iin is maintained at a constant value as illustrated in FIG. 7A, the integrated voltage signal Vo output from the charge integration circuit 3 keeps increasing as illustrated in FIG. 7B. When, subsequently, the integrated voltage signal Vo reaches the reference voltage V1 at a point of time t2, the comparison signal Sc output from the voltage comparison circuit 51 is reversed from the low-level to the high-level as illustrated in FIG. 7C.

Because the comparison signal Sc at the high-level is supplied to the pulse signal generation circuit 52, the pulse signal P1 with a predetermined pulse width is output from the pulse signal generation circuit 52 as illustrated in FIG. 7D. Because the pulse signal P1 is input to the counter circuit 53, the counter circuit 53 starts counting the clock pulses and the count value N increases.

On the other hand, the pulse signal P1 output from the pulse signal generation circuit 52 is supplied to the pumping capacitor 71 of the pumping circuit 7. Thus, when the pulse signal P1 rises to the high-level, charge charged in the pumping capacitor 71 flows to the ground via the resistor 73 during the rise, and a positive voltage is generated at the connection point of the pumping capacitor 71 and the resistor 73. Because the voltage is applied to the pumping diode 72 as a forward voltage, the pumping diode 72 conducts to make a current flow, causing charge stored in the integrating capacitor 32 of the charge integration circuit 3 to be discharged.

Therefore, the integrated voltage signal Vo output from the charge integration circuit 3 decreases steeply to a neighborhood of “0” while the pulse signal P1 is maintained at the high-level, as illustrated in FIG. 7B.

When, subsequently, the pulse signal P1 returns from the high-level to the low-level at a point of time t3, discharging from the integrating capacitor 32 by the pumping circuit 7 is stopped, integration processing is started again in the charge integration circuit 3, and the integrated voltage signal Vo increases again as illustrated in FIG. 7B.

When, subsequently, the integrated voltage signal Vo keeps increasing and reaches the reference voltage V1 again at a point of time t4, a high-level comparison signal Sc is output from the voltage comparison circuit 51, causing the pulse signal generation circuit 52 to generate the pulse signal P1 with a predetermined width.

Every time the pulse signal P1 is supplied, the counter circuit 53 transfers, to an internal memory, a count value of the clock which has been counted since the time of the last input of the pulse signal P1, clears the count value to “0”, and continues counting the clock. Thus, except the time of input of the pulse signal P1 immediately after the start-up, a measured value of the cycle T of the pulse signal P1 is obtained every time the pulse signal P1 is supplied, and a count value N indicating the cycle T of the integrated voltage signal Vo at that time is input to the arithmetic processing circuit 42 each time.

Because the arithmetic processing circuit 42 carries out the high range current measurement processing illustrated in FIG. 4 as timer interrupt processing, the cycle T of the integrated voltage signal Vo is input from the counter circuit 53 when the execution of the high range current measurement processing is started. Thus, in the high range current measurement processing, the frequency f of the integrated voltage signal Vo is calculated based on the cycle T (step S42), and the high range current measurement value Im_{H} is calculated by multiplying the calculated frequency f by a conversion factor Kf (step S43).

The high range current measurement processing then updates and stores the calculated high range current measurement value Im_{H} in a high range current measurement value storage area of the memory (step S44), and sets the flag CNF, which indicates whether or not the pulse signal P1 is input, at “1” in the counter circuit.

Then, the high range current measurement processing adds 1 to Nh, which is a value to distinguish areas storing the high range current measurement values, that is, increases Nh by 1 (step S46), and, when Nh is less than 8, ends the timer interrupt processing without any processing, and, when Nh is 8 or greater, sets Nh at 0 in step S48, ends the timer interrupt processing, and returns to the predetermined main program.

Because the current to be measured Iin is −10⁻¹² A or higher at this time, the cycle T of the integrated voltage signal Vo becomes 1 second or shorter. Thus, when the measurement value determination processing in FIG. 6, which is carried out as timer interrupt processing, is carried out, for example, once every second in the arithmetic processing circuit 42, the process proceeds from step S61 to step S62, an additional value Ims of valid data (≠0) among the high range current measurement values Im_{H}(0) to Im_{H}(7) is calculated, and the number of pieces of valid data (≠0) j is calculated. Then, the process proceeds to step S63, an average value is calculated by dividing the additional value Ims by the number of pieces of valid data j, the calculated average value is determined as the current measurement value Im of the current to be measured Iin, and the determined current measurement value Im is updated and stored in the current measurement value storage area of the memory and output to the outside (step S63).

When the current value of the current to be measured Iin, which is input to the current input terminal 2, is lower than −10⁻¹² A, however, the cycle T of the integrated voltage signal Vo output from the charge integration circuit 3 becomes longer than 1 second. Thus, when the current to be measured Iin is −10⁻¹⁵ A, which is a minimum measurable current value, the cycle T of the integrated voltage signal Vo becomes 1000 seconds. Therefore, it takes 1000 seconds for the cycle T to be output from the counter circuit 53, making it totally impossible for the high range current measurement unit 5 to cope with a case in which current measurement is required to be carried out once every second.

When 2 seconds or longer has passed since the pulse signal P1 was input to the counter circuit 53, every time the high range current measurement value storage area invalidation processing illustrated in FIG. 5 is carried out as timer interrupt processing, processing in which a high range current measurement value Im_{H}(Nh) specified by Nh, which is a value to distinguish storage areas in the high range current measurement value storage area, is updated and stored with “0” is repeated (steps S50 to S54).

On the other hand, current measurement is carried out in a short period of time of shorter than 1 second in the low range current measurement unit 4. That is, in the low range current measurement unit 4, the integrated voltage signal Vo output from the charge integration circuit 3 is always input to the A/D conversion circuit 41, and the integrated voltage signal Vo is converted to the digital signal Vod in a sampling period of approximately 4 or 5 times per second in the A/D conversion circuit 41. The digital signal Vod output from the A/D conversion circuit 41 is supplied to the arithmetic processing circuit 42.

In the arithmetic processing circuit 42, the low range current measurement processing illustrated in FIG. 3 is carried out as timer interrupt processing with a period corresponding to the sampling period of the A/D conversion circuit 41. In the low range current measurement processing, the rate of change Rc per unit time of the integrated voltage signal Vo takes a value proportional to the current to be measured Iin in a rising process of the integrated voltage signal Vo from the point of time t1 to the point of time t2 as illustrated in FIG. 7B. However, in a falling process from the point of time t2 to the point of time t3, the rate of change Rc per unit time of the integrated voltage signal Vo does not take a value proportional to the current to be measured Iin, and the digital signal(s) Vod(n) during the process is/are discarded.

Accordingly, when the execution of the low range current measurement processing is started, it is determined whether or not the low range current measurement processing is the discard processing of the digital signal(s) Vod(n) (step S31), and, when FP1==“0”, that is, not the discard processing, it is determined whether or not the pulse signal P1 has been input to the counter circuit 53 based on whether or not the flag CNF, which indicates whether or not the pulse signal P1 is input, is equal to “1” (step S32).

When the pulse signal P1 has not been input to the counter circuit 53, that is, the flag CNF is reset at “0”, a digital signal Vod(n) output from the A/D conversion circuit 41 is read (step S33).

The low range current measurement processing also calculates the rate of change Rc per unit time by dividing a difference between the digital signal Vod(n) read in step S33 and the digital signal Vod(n−1) at the last timer interruption by the timer interrupt period (step S34).

Then, the low range current measurement processing calculates the low range current measurement value Im_{L} (=Rc×Kc) by multiplying the calculated rate of change Rc per unit time by a conversion factor Kc (step S35) and updates and stores the calculated low range current measurement value Im_{L} in the low range current measurement value storage area (step S36). The low range current measurement processing sets the flag CNF, which indicates whether or not the pulse signal P1 has been input, at “0” so as to be able to detect that the pulse signal P1 has been input to the counter circuit 53, and then ends the timer interrupt processing and returns to the predetermined main program.

When the pulse signal P1 is input to the counter circuit 53 as illustrated in FIG. 7C, the discard processing of the digital signal(s) Vod(n) is started because the integrated voltage signal Vo comes to fall steeply. In this case, the process proceeds from step S32 to step S40 in which the flag FP1 is set at “1”, and then the process proceeds to step S37 in which the flag CNF is reset at “0”. Corresponding to this process, the arithmetic processing circuit 42 ends the timer interrupt processing without carrying out low range current measurement value calculation and returns to the predetermined main program.

Therefore, when a predetermined period has passed and the next round of the low range current measurement processing is started, the process proceeds to step S38 in a case in which the flag FP1 is “1” (in discard processing) in step S31. In this step S38, a digital signal Vod(n) is read and held so as to be able to calculate the rate of change in step S34 of the next round of the processing, the flag FP1 is then set at “0” in step S39, and the process proceeds to step S37 in which the flag CNF is reset at “0”. Therefore, the arithmetic processing circuit 42 ends the timer interrupt processing without carrying out low range current measurement value calculation and returns to the predetermined main program. In this way, when the pulse signal P1 is input to the counter circuit 53, at least one digital signal Vod(n) is discarded without being read.

Once the low range current measurement value Im_{L} is stored in the low range current measurement value storage area, when the afore-described measurement value determination processing in FIG. 6 is carried out by the arithmetic processing circuit 42 thereafter, the process proceeds from step S61 to step S64 if 2 seconds or longer has passed since the last input of the pulse signal P1 to the counter circuit 53. Accordingly, processing is carried out in which the high range current measurement values Im_{H} are weighted in accordance with the frequency of the pulse signal P1, and an average value of the weighted high range current measurement values Im_{H} and the low range current measurement value Im_{L} is calculated and determined to be a current measurement value Im of the current to be measured Iin (steps S64 to S70).

That is, numerals i and j are set at “0” and the additional value Ims is set at “0” (step S64). When a high range current measurement value Im_{H}(i) takes a value other than “0”, a new additional value Ims is calculated by adding the high range current measurement value Im_{H} to the current additional value Ims (step S66). Then, the number of pieces of valid data j is increased by only “1” (step S67), and the process proceeds to step S68.

When it is determined in step S65 that the high range current measurement value Im_{H}(i) is “0”, the process proceeds to step S68 without carrying out addition processing.

In this step S68, the number of additions i is increased by only “1” and the process proceeds to step S69 in which the process returns to step S65 when i<8 is satisfied, and the process proceeds to step S70 when i≧8 is satisfied. In this step S70, an average value is calculated by dividing an additional value, which is calculated as the additional value Ims added by the low range current measurement value Im_{L}, by j+1, which is calculated as the number of pieces of valid data j added by “1”, and the calculated average value is stored as a current measurement value Im of the current to be measured Iin and output to the outside.

In consequence, when repeating processing in steps S65 to S69 in the measurement value determination processing eight times results in Im_{H}(0) to Im_{H}(7) all having a value of “0”, the low range current measurement value Im_{L} is determined as the current measurement value Im. When at least one or more high range current measurement values Im_{H} exist, an average value is calculated by dividing an additional value, which is calculated as the additional value Ims of these high range current measurement values Im_{H} added by the low range current measurement value Im_{L}, by a value, which is calculated as the number of pieces of valid data j added by “1”. The calculated average value is determined as the current measurement value Im.

As described above, according to the above-described first embodiment, when it is possible to calculate a high range current measurement value Im_{H} with respect to a desired timing of a measurement value output request in the high range current measurement unit 5, the high range current measurement value Im_{H} is determined as the current measurement value Im for the current to be measured Iin. When it is not possible to calculate a high range current measurement value Im_{H} within a desired timing of a measurement value output request, the low range current measurement value Im_{L} calculated by the low range current measurement unit 4 is determined as the current measurement value Im for the current to be measured Iin. Further, when one or more high range current measurement values Im_{H} are calculated within a timing of a measurement value output request, an average value calculated by dividing an additional value of the sum of the calculated high range current measurement values Im_{H} and the low range current measurement value Im_{L} by j+1, which is calculated as the number of pieces of valid data j among the high range current measurement values Im_{H} increased by “1”, is determined as the current measurement value Im.

Accordingly, it is possible to calculate a current measurement value for a minute current with a wide range of values from −10⁻¹⁵ A to −10⁻⁶ A, that is, a 9 digit range, accurately without range switching at a desired timing of a measurement value output request.

Furthermore, in the low range current measurement unit 4, because the rate of change Rc per unit time of the integrated voltage signal Vo output from the charge integration circuit 3 is calculated and the low range current measurement value Im_{L} is calculated by multiplying the rate of change Rc by the conversion factor Kc, it is possible to carry out measurement accurately in a short period of time within a desired timing of a measurement value output request even when the current to be measured Iin is in a neighborhood of a minimum current value of −10⁻¹⁵ A.

In the high range current measurement unit 5, because the high range current measurement value Im_{H} is calculated based on a pulse signal generated when the integrated voltage signal Vo output from the charge integration circuit 3 reaches a reference voltage, it is also possible to carry out an accurate current measurement.

Further, because calculation of the low range current measurement value Im_{L} and calculation of the high range current measurement value Im_{H} are carried out at the same time, and selection from the values is carried out based on whether or not it is possible to calculate the high range current measurement value Im_{H} within a desired timing of a measurement value output request, no loss time due to range switching is caused, making it possible to accurately measure a current to be measured with a wide range of values.

A relationship between the value of a current to be measured and the rate of change of the integrated voltage signal Vo in the low range current measurement unit 4 and a relationship between the value of the current to be measured and the frequency of the integrated voltage signal in the high range current measurement unit 5 are illustrated in FIGS. 8A and 8B, respectively.

It is possible to obtain the high range current measurement value Im_{H} calculated by the high range current measurement unit 5 by measuring the frequency of the pulse signal P1 output from the pulse signal generation circuit 52, which drives the pumping circuit 7. The current to be measured Iin of from 1 pA to 1 μA corresponds to the frequency of the pulse signal P1 of from 0.5 Hz to 500 kHz as illustrated in FIG. 8B.

In this case, when a current of 1 μA flows for a duration of 1/500 kHz, charge thereof becomes 2 pC=1 μA/500 kHz. Because the charge balances with charge pumped by the pumping circuit 7, when the voltage of the integrated voltage signal Vo output from the charge integration circuit 3 is to be changed by, for example, 1 V in one pumping operation, the capacitance C of the integrating capacitor 32 is calculated by the following equation:

C=Q/V=2 pC/1 V=2 pF.

It is possible to obtain the low range current measurement values Im_{L} calculated by the low range current measurement unit 4 by, as described above, converting the integrated voltage signal Vo output from the charge integration circuit 3 to the rate of change Rc per unit time and multiplying the rate of change Rc by the conversion factor Kc. When it is assumed that the capacitance of the integrating capacitor 32 of the charge integration circuit 3 is 2 pF, the voltage change per second corresponding to the current to be measured Iin of from 1 fA to 3 pA is illustrated in FIG. 8A.

When it is assumed that the current to be measured Iin is 1 fA, because the capacitance of the integrating capacitor 32 is 2 pF, the voltage change per second ΔVo of the integrated voltage signal Vo output from the charge integration circuit 3 is calculated by the following equation:

ΔVo=1 (fC)/2000 (fF)=0.5 mV,

and a circuit which makes it possible to measure the above-described voltage with a required precision is chosen as the A/D conversion circuit 41. For example, when a precision of 1% is required, it is necessary to be able to measure a voltage of 0.005 mV, which is 1/100 of the afore-described voltage of 0.5 mV, and, when it is assumed that the maximum measurement voltage is 1 V, a resolution of 200,000 (1 V/0.000005 V) (18 bits or greater) is required.

Further, when the pulse signal generation circuit 52 of the high range current measurement unit 5 is configured to be able to change the wave height of an output signal, it conveniently becomes possible to normalize the relationship between the current to be measured Iin and the pulse signal P1 to be output by absorbing errors in circuit constants. Because the highest frequency of the pulse signal P1 is 500 kHz, the pulse width of the pulse signal P1 output from the pulse signal generation circuit 52 is set at approximately 0.4 μs in a case in which the duty ratio is assumed to be, for example, 20%.

Because a current pumped by the pumping circuit 7 balances with an input current to the high range current measurement unit 5, the amount of charge acquired by integrating a current of 1 μA for a duration of 1/500 kHz becomes 2 pC, which is equivalent to an amount of charge pumped by a single pulse signal P1 output from the pulse signal generation circuit 52. When it is assumed that the effective wave height of an output voltage of the pulse signal generation circuit 52 is, for example, 0.1 V, the capacitance C1 of the pumping capacitor 71 is calculated by the following equation:

C=Q/V=2 pC/0.1 V=20 pF.

When it is assumed that, because the pulse width of the pulse signal generation circuit 52 is approximately 0.4 μs, the product of the resistance value of the resistor 73 multiplied by the capacitance of the pumping capacitor 71 (τp: time constant of the pumping circuit) is set at a sufficiently small value of, for example, 0.04 μs ( 1/10) with respect to the pulse width of 0.4 μs of the pulse signal P1 output from the pulse signal generation circuit 52 so that the pumping capacitor 71 is sufficiently charged and discharged within the above-described time of 0.4 μs, the resistance value R2 of the resistor 73 is calculated by the following equation:

R2=0.04 (μs)/20 (pF)=2 (kΩ).

However, in actuality, it is necessary to take into consideration a voltage corresponding to a forward voltage drop of the pumping diode 72 and energy loss due to capacitance between the electrodes of the pumping diode 72.

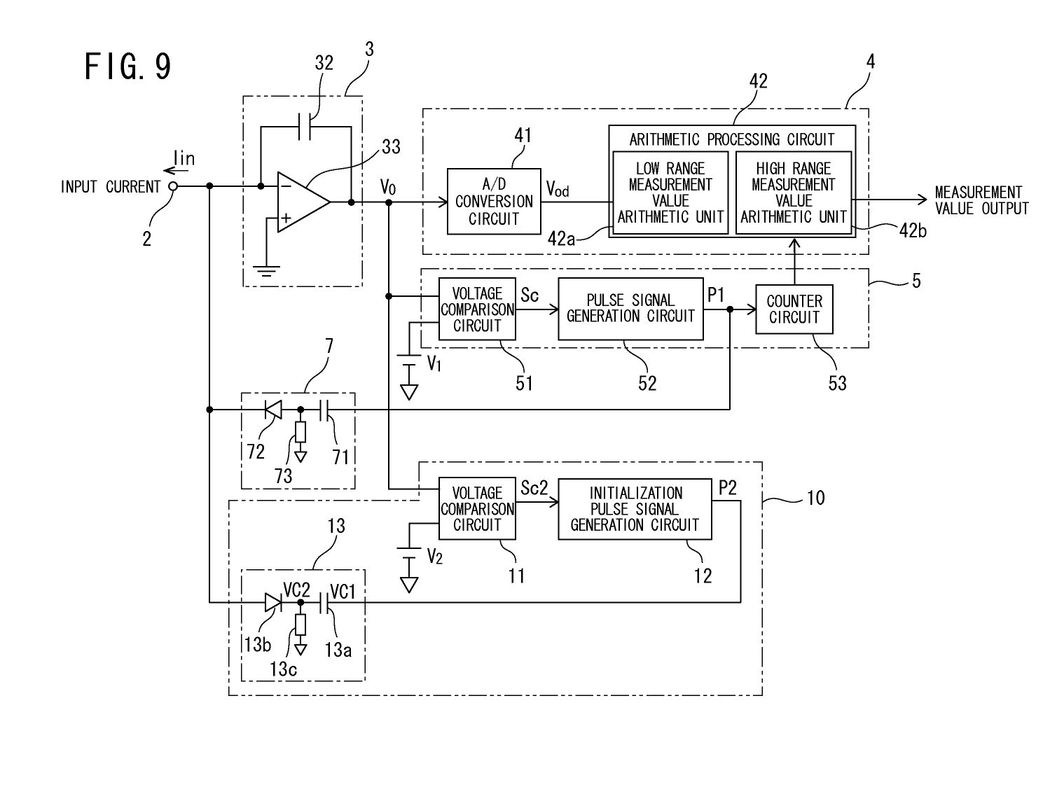

Next, a second embodiment as another aspect of the present disclosure will be described with reference to FIG. 9.

The second embodiment has a configuration that suppresses production of invalid data when a current value of a current to be measured Iin becomes lower than or equal to a lower limit of a range of voltage which is convertible by an A/D conversion circuit 41 composing a low range current measurement unit 4.

That is, the second embodiment has the same configuration as the configuration illustrated in FIG. 2 except that an initialization circuit 10 is disposed in parallel with a high range current measurement unit 5 in the above-described first embodiment as illustrated in FIG. 9. Identical signs are assigned to components corresponding to the components in FIG. 2, and detailed description thereof will be omitted.

The initialization circuit 10 includes a voltage comparison circuit 11, an initialization pulse signal generation circuit 12 and an initialization pumping circuit 13.

The voltage comparison circuit 11 receives an integrated voltage signal Vo output from the charge integration circuit 3 and, as an initialization voltage, a lower limit voltage V2 of a range of voltage which is A/D convertible by the A/D conversion circuit 41 composing the low range current measurement unit 4, and outputs a high-level comparison signal Sc2 when the integrated voltage signal Vo is lower than the lower limit voltage V2.

The comparison signal Sc2 is supplied from the voltage comparison circuit 11 to the initialization pulse signal generation circuit 12. The initialization pulse signal generation circuit 12 outputs an initialization pulse signal P2 with a predetermined width and a predetermined wave height, which falls from the high-level to the low-level when the comparison signal Sc2 is inverted from the low-level to the high-level.

The initialization pumping circuit 13 is configured to receive the initialization pulse signal P2 output from the initialization pulse signal generation circuit 12, have a function with reversed polarity to the pumping circuit 7, and work in a direction in which charge is stored in the charge integration circuit, not in a direction in which charge in the charge integration circuit is discharged.

That is, the initialization pumping circuit 13 includes a pumping capacitor 13a, a pumping diode 13b, and a resistor 13c as illustrated in FIG. 9. One pole of the pumping capacitor 13a is connected to the output side of the pulse signal generation circuit 12, and the pumping diode 13b is interposed between the other pole of the pumping capacitor 13a and the integrating capacitor 32 of the charge integration circuit 3.

The anode and cathode of the pumping diode 13b are connected to the integrating capacitor 32 and the pumping capacitor 13a, respectively. The resistor 13c is connected between the connection point of the pumping capacitor 13a and the pumping diode 13b and the ground.

Thus, in the initialization pumping circuit 13, when the pulse signal P2 supplied from the initialization pulse signal generation circuit 12 to the pumping capacitor 13a is at the high-level, a voltage VC1 at the electrode on the initialization pulse signal generation circuit 12 side of the pumping capacitor 13a becomes a charging voltage V_{H} of the pulse signal P2, and charge corresponding to the charging voltage V_{H} is stored in the pumping capacitor 13a. A charging current flows via the resistor 13c while charge is stored, causing a voltage VC2 on the capacitor 13a side of the resistor 13c to be a positive voltage. Even when the voltage is supplied to the cathode of the pumping diode 13b, the pumping diode 13b stays in the off-state and no current flows to the charge integration circuit 3. When charging has finished, the voltage VC2 at the electrode on the pumping diode 13b side of the pumping capacitor 13a becomes 0 V.

When the pulse signal P2, which is supplied from the initialization pulse signal generation circuit 12 to the pumping capacitor 13a, falls to the low-level while the circuit is in the above-described state, the voltage VC1 at the electrode on the initialization pulse signal generation circuit 12 side becomes a voltage V_{L}, a discharge current flows through the pumping capacitor 13a, the current flows through the resistor 13c, and the voltage VC2 at the electrode on the pumping diode 13b side transitions to a negative voltage value corresponding a difference voltage VC(=V_{H}−V_{L}) between the high-level and the low-level. Thus, the voltage VC2 on the cathode side of the pumping diode 13b falls to a negative voltage value, the pumping diode 13b turns to the on-state, and a portion of the discharge current of the pumping capacitor 13a flows. With this operation, charge is stored in the integrating capacitor 32 of the charge integration circuit 3, causing the integrated voltage signal Vo to increase. At this time, when a single pulse signal P2 is not enough for the integrated voltage signal Vo to rise to the lower limit voltage V2, which is an initialization voltage, or higher, the initialization pulse signal generation circuit may have a function to generate a plurality of initialization pulse signals P2 until the integrated voltage signal Vo reaches the lower limit voltage V2. When the integrated voltage signal Vo rises to the lower limit voltage V2, which is an initialization voltage, or higher, the comparison signal Sc2 output from the voltage comparison circuit 11 returns to the low-level.

Because the initialization pulse signal P2 output from the initialization pulse signal generation circuit 12 has a predetermined width, the initialization pulse signal P2 returns to the high-level in a predetermined period after a fall. With this operation, the pumping diode 13b of the initialization pumping circuit 13 returns to the off-state, and storage of charge from the initialization pumping circuit 13 to the integrating capacitor 32 is stopped.

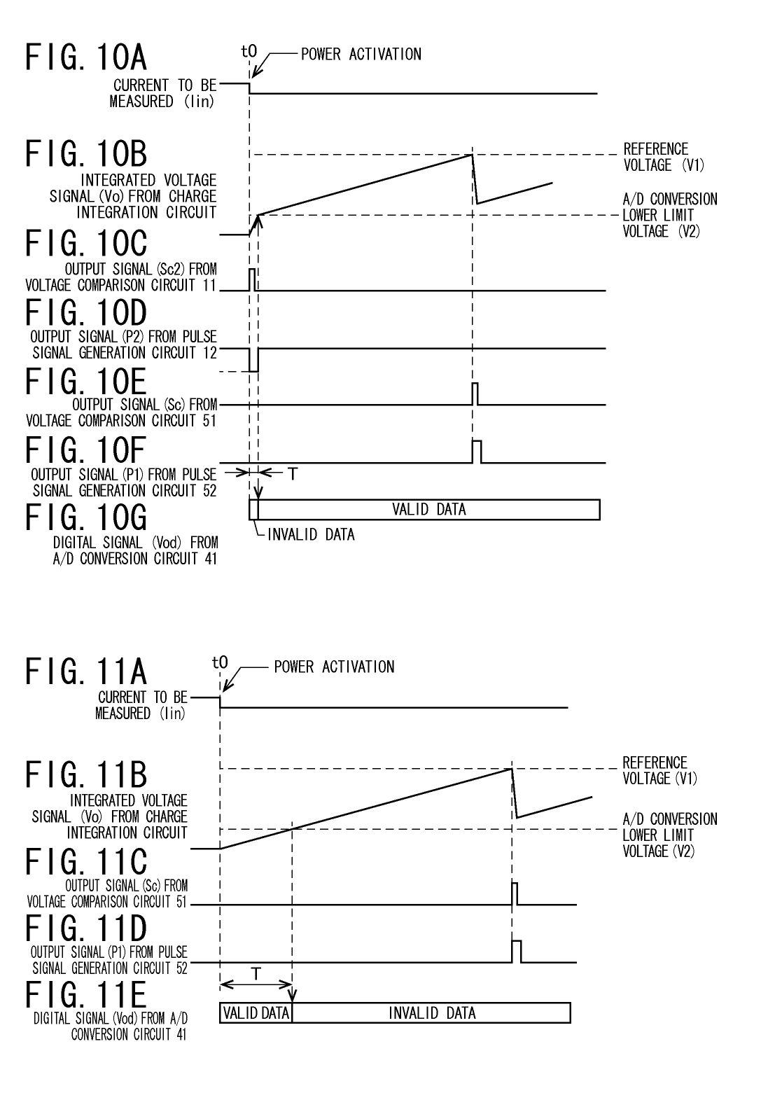

Next, operations of the above-described second embodiment will be described with reference to FIGS. 10A to 10G.

When a current to be measured Iin having a negative value is input to the current input terminal 2, the current to be measured Iin is supplied to the charge integration circuit 3, and a voltage value of the integrated voltage signal Vo output from the charge integration circuit 3 surpasses a lower limit voltage V2 of a range of voltage which is A/D convertible by the A/D conversion circuit 41 composing the low range current measurement unit 4, a valid digital signal Vod is output from the A/D conversion circuit 41, making it possible to achieve the same advantageous effect as the afore-described first embodiment.

However, when, as illustrate in FIG. 10B, the integrated voltage signal Vo output from the charge integration circuit 3 based on the current to be measured Iin input to the current input terminal 2 is lower than the lower limit voltage V2, which is an initialization voltage, of the A/D conversion circuit 41 composing the low range current measurement unit 4 due to some reason, such as power activation and noise contamination, it is not possible to obtain an valid digital signal Vod from the A/D conversion circuit 41.

Because the integrated voltage signal Vo is lower than the lower limit voltage V2 when the circuit is in this state, the comparison signal Sc2 output from the voltage comparison circuit 11 of the initialization circuit 10 rises to the high-level, and an initialization pulse signal P2 at the low-level V_{L} is output from the initialization pulse signal generation circuit 12 to the initialization pumping circuit 13.

Thus, the voltage VC1 at the electrode on the initialization pulse signal generation circuit 12 side of the pumping capacitor 13a of the initialization pumping circuit 13 falls to the voltage V_{L}, and a discharge current flows to the pumping capacitor 13a via the resistor 13c. Because a negative voltage, which is the product of the discharge current value multiplied by the resistance of the resistor 13c, is generated to the voltage VC2 at the electrode on the pumping diode 13b side, the pumping diode 13b turns to the on-state. With this operation, charge is stored in the integrating capacitor 32 of the charge integration circuit 3, causing the integrated voltage signal Vo to rise steeply as illustrated in FIG. 10B.

Because the initialization pulse signal P2 returns to the high-level after outputting a pulse with a predetermined width, the voltage VC1 at the electrode on the initialization pulse signal generation circuit 12 side of the pumping capacitor 13a of the initialization pumping circuit 13 rises to the charging voltage V_{H}, causing charge corresponding to the charging voltage V_{H} to be stored in the pumping capacitor 13a. A charging current flows via the resistor 13c while charge is being stored, and the voltage VC2 on the capacitor 13a side of the resistor 13c changes to a positive voltage. Even when the voltage is supplied to the cathode of the pumping diode 13b, the pumping diode 13b stays in the off-state and no current flows to the charge integration circuit 3. When charging has finished, the voltage VC2 at the electrode on the pumping diode 13b side of the pumping capacitor 13a falls to 0V.

When the circuit transitions to this state, the pumping diode 13b turns to the off-state, causing the initialization pumping circuit 13 to stop storing charge in the integrating capacitor 32.

When a single supply of the initialization pulse signal P2 from the initialization pulse signal generation circuit 12 to the initialization pumping circuit 13 is not enough for the integrated voltage signal Vo to reach the lower limit voltage V2 of the A/D conversion circuit 41, the supply of the initialization pulse signal P2 is continued until the integrated voltage signal Vo reaches the lower limit voltage V2.

When the integrated voltage signal Vo reaches the lower limit voltage V2 of the A/D conversion circuit 41 by the supply of one or a plurality of initialization pulse signals P2 from the initialization pulse signal generation circuit 12 to the initialization pumping circuit 13, the comparison signal Sc2 output from the voltage comparison circuit 11 returns to the low-level. In response to the change, the initialization pulse signal P2 output from the initialization pulse signal generation circuit 12 stops pulsing and stays in a state in which the initialization pulse signal P2 has returned to the high-level.

When the circuit proceeds to this state, because the pumping diode 13b turns to the off-state, storage of charge in the integrating capacitor 32 by the initialization pumping circuit 13 is stopped, and the initialization processing by the initialization circuit 10 is ended.

As described above, when the integrated voltage signal Vo reaches the lower limit voltage V2 of a range of voltage which is A/D convertible by the A/D conversion circuit 41, the digital signal Vod output from the A/D conversion circuit 41 becomes valid data. Thereafter, as with the afore-described first embodiment, the integrated voltage signal Vo repeats an integration state and a discharging state by operations of the pulse signal generation circuit 52 of the high range current measurement unit 5 and the pumping circuit 7 based on the integrated voltage signal Vo, making it possible to calculate the low range current measurement value Im_{L} accurately in the low range current measurement unit 4.

As described above, according to the second embodiment, when the integrated voltage signal Vo output from the charge integration circuit 3 is lower than the lower limit voltage V2 of a range of voltage which is A/D convertible by the A/D conversion circuit 41 composing the low range current measurement unit 4, the integrated voltage signal Vo is raised steeply to the lower limit voltage V2 by the initialization circuit 10. Thus, it is possible to suppress production of invalid data in the A/D conversion circuit 41 and surely suppress elongation of measurement time of the low range current measurement value.

If it is assumed that the initialization circuit 10 is not included, in a case in which, when the power is applied at a point of time t0 as illustrated in FIG. 11A, the integrated voltage signal Vo, which is an integrated value of the current to be measured Iin by the charge integration circuit 3, is lower than the lower limit voltage V2 of the A/D conversion circuit 41 as illustrated in FIG. 11B, a time T taken for the integrated voltage signal Vo to reach the lower limit voltage V2 of the A/D conversion circuit 41 by integration in the charge integration circuit 3 is elongated. Thus, a period T for which the digital signal Vod output from the A/D conversion circuit 41 is regarded to be invalid data increases as illustrated in FIG. 11E, and the start of current measurement in the low range current measurement unit 4 is delayed by the time T.

At this time, when it is assumed that, for example, the integrated voltage signal Vo is −1 V, the lower limit voltage V2 is 0 V, the current to be measured Iin is 10 fA, and the capacitance of the integrating capacitor 32 is 2 pF, charge required to raise the integrated voltage signal Vo output from the charge integration circuit 3 from −1 V to 0 V is −2 pC(=−1 V×2 pF). Although the charge is attained by storing an input current of 10 fA, the time T required for the integrated voltage signal Vo output from the charge integration circuit 3 to rise to the lower limit voltage V2 or higher when the current to be measured Iin is 10 fA becomes

T (s)=2 (pC)/0.01 (pA)=200 (s),

indicating that it is not possible to obtain the low range current measurement value Im_{L} of the current to be measured for 200 seconds.

On the other hand, in the above-described second embodiment, it is possible to raise the integrated voltage signal Vo to the lower limit voltage V2 of the A/D conversion circuit 41 in an instant by storing charge in the integrating capacitor 32 of the charge integration circuit 3 by using the initialization circuit 10. It is possible to suppress the time required for the initialization to approximately 1 μs because the time is a duration for which a pulse is output from the initialization pulse signal generation circuit 12.

In the second embodiment, because operations in the initialization circuit 10 are reversed operations of operations in the high range current measurement unit 5 and the pumping circuit 7, by setting the initialization voltage V2, which is a lower limit voltage supplied to the voltage comparison circuit 11, at a negative value −V1 of the reference voltage V1, it becomes possible to calculate the high range current measurement value Im_{H} in a case in which the polarity of the current to be measured Iin is assumed to be positive.

Although, in the above-described second embodiment, a case in which the reference voltage supplied to the voltage comparison circuit 11 of the initialization circuit 10 is set at the lower limit voltage V2 of the A/D conversion circuit 41 is described, any value that makes the time T, during which invalid data are output, within an acceptable range may be set to the reference voltage as long as the value is less than or equal to the lower limit voltage V2.

Although, in the above-described first and second embodiments, a case in which the low range current measurement unit 4 is configured with the A/D conversion circuit 41 and the arithmetic processing circuit 42 is described, the configuration is not limited to the case. According to an aspect of the present disclosure, two voltage comparison circuits to which different reference voltages with a small voltage difference are set may be disposed, the integrated voltage signal Vo output from the charge integration circuit 3 may be fed to the voltage comparison circuits, and, based on a time difference between comparison signals output from the voltage comparison circuits, the rate of change in the integrated voltage signal Vo may be calculated. In other words, any configuration may be applied as long as it is possible to calculate the rate of change Rc of the integrated voltage signal Vo by the configuration. An averaged value of a plurality of low range current measurement values Im_{L} calculated for every predetermined period by the low range current measurement unit 4 may be calculated as the low range current measurement value Im_{L}.

In the above-described first and second embodiments, a voltage-to-frequency conversion circuit may also be disposed with respect to the high range current measurement unit 5, and the integrated voltage signal Vo may be converted a frequency signal directly.

Further, in the above-described first and second embodiments, a case in which the arithmetic processing circuit 42 is disposed and the arithmetic processing circuit 42 carries out the low range current measurement processing, the high range current measurement processing, the high range current measurement value storage area invalidation processing and the measurement value determination processing is described. The disclosure is not limited to this case, and the low range measurement value arithmetic unit 42a and the high range measurement value arithmetic unit 42b may be separately disposed to the low range current measurement unit 4 and the high range current measurement unit 5.

Although, in the above-described first and second embodiments, a case in which the current to be measured Iin takes a negative value is described, the configuration is not limited to the case. When a positive current to be measured Iin is input, because the integrated voltage signal Vo output from the charge integration circuit 3 decreases from 0 in the negative direction, the polarity of the reference voltage V1 may be set at a negative value and calculation of the rate of change may be carried out by subtracting the current value from the previous value.

Further, in the above-described first and second embodiments, a case in which temperature dependence of the pumping diode 72 composing the pumping circuit 7 is not taken into consideration is described. It is also possible that, when temperature dependence of the pumping diode 72 is taken into consideration, the temperature of the pumping diode 72 may be actually measured by a temperature sensor, and a temperature compensation circuit, which is configured to adjust the pulse width of the pulse signal P1 output from the pulse signal generation circuit 52 by a variance in the forward voltage of the pumping diode 72 at a temperature actually measured by the temperature sensor, may be disposed as described in the afore-described Japanese Patent No. 4479430.

1. A current measurement device, a current measurement range of a current to be measured by the current measurement device being divided into at least a low range and a high range, the current measurement device carrying out current measurement in each of the low range and the high range, the current measurement device comprising:
an integration circuit configured to integrate the current to be measured and output an integral signal;
a low range current measurement unit configured to receive the integral signal output from the integration circuit and calculate a low range current measurement value that is proportional to a rate of change of the integral signal;
a high range current measurement unit configured to calculate a high range current measurement value based on a pulse signal corresponding to a cycle of the integral signal output from the integration circuit;
a pumping circuit configured to discharge charge stored in the integration circuit based on the pulse signal; and
a measurement value determination unit configured to determine a measurement value of the current to be measured based on the low range current measurement value calculated by the low range current measurement unit and the high range current measurement value calculated by the high range current measurement unit.

2. The current measurement device according to claim 1,
wherein the low range current measurement unit comprises an analog-to-digital (A/D) conversion circuit configured to convert the integral signal output from the integration circuit to a digital signal and a low range measurement value arithmetic unit configured to calculate a rate of current change per unit time of the digital signal output from the A/D conversion circuit and calculate the low range current measurement value by multiplying the calculated rate of current change by a conversion factor.

3. The current measurement device according to claim 1,
wherein the high range current measurement unit comprises a pulse signal generation circuit configured to compare the integral signal output from the integration circuit with a reference signal and output the pulse signal when the integral signal surpasses the reference signal and a high range measurement value arithmetic unit configured to count the number of pulses per unit time of the pulse signal output from the pulse signal generation circuit to calculate the high range current measurement value.

4. The current measurement device according to claim 1,
wherein the integration circuit comprises an initialization circuit configured to determine an initial value of the integral signal to be output in inputting the current to be measured.

5. The current measurement device according to claim 4,
wherein the initialization circuit comprises an initialization pulse signal generation circuit configured to compare the integral signal output from the integration circuit with an initialization voltage and generate an initialization pulse signal when the integral signal has a voltage lower than the initialization voltage and an initialization pumping circuit configured to store charge stored in the integration circuit based on the initialization pulse signal output from the initialization pulse signal generation circuit.

6. The current measurement device according to claim 5,
wherein the initialization voltage is a lower limit voltage of a range of voltage which is convertible by the A/D conversion circuit included in the low range current measurement unit.
